(19) United States
(12) Patent Application Publication
(10) Pub. No.: US 2023/0064147 A1
(43) Pub. Date: Mar. 2, 2023

(54) BUFFER CIRCUIT CAPABLE OF ADJUSTING A GAIN, RECEIVING CIRCUIT AND SEMICONDUCTOR APPARATUS INCLUDING THE SAME

(71) Applicant: SK hynix Inc., Icheon-si Gyeonggi-do (KR)

(72) Inventor: Sun Ki CHO, Icheon-si Gyeonggi-do (KR)

(73) Assignee: SK hynix Inc., Icheon-si Gyeonggi-do (KR)

(21) Appl. No.: 17/552,283

(22) Filed: Dec. 15, 2021

(30) Foreign Application Priority Data
Aug. 30, 2021 (KR) 10-2021-0114739

(51) Int. Cl. G05F 1/56

(52) U.S. Cl. CPC G05F 1/56

(57) ABSTRACT

A buffer circuit receives a first input signal and a second input signal to generate a first output signal and a second output signal. The buffer circuit includes a load circuit. The load circuit receives a gain adjustment signal. The load circuit increases a total gain of the buffer circuit when the gain adjustment signal is disabled and increases an AC gain of the buffer circuit when the gain adjustment signal is enabled.

### CROSS-REFERENCES TO RELATED APPLICATION

The present application claims priority under 35 U.S.C. § 119(a) to Korean application number 10-2021-0114739, filed on Aug. 30, 2021, in the Korean Intellectual Property Office, which is incorporated herein by reference in its entirety as set forth in full.

### BACKGROUND

### 1. Technical Field

Various embodiments generally relate to an integrated circuit technology, and, more particularly, to a buffer circuit and a receiving circuit and a semiconductor apparatus including the same.

### 2. Related Art

An electronic device includes a lot of electronic elements and a computer system as the electronic device includes lots of semiconductor apparatuses each configured by a semiconductor. The semiconductor apparatuses configuring the computer system may communicate with each other by transmitting and receiving a clock signal and data. Each of the semiconductor apparatuses may include a buffer circuit configured to amplify an input signal and/or buffer the input signal to generate an output signal. A general buffer circuit may be a differential amplifier configured to differentially amplify a positive input signal and a negative input signal to generate an output signal. As an operational speed of a semiconductor apparatus increases, a duty ratio of an output signal that is generated by the buffer circuit is apt to be distorted. Even though proposed is a buffer circuit including a circuit configured to adjust the duty ratio of the output signal, the gain and bandwidth of the buffer circuit may decrease due to the load of the circuit included in the buffer circuit.

### SUMMARY

In an embodiment, a buffer circuit may include a first input transistor, a second input transistor, and a load circuit. The first input transistor may be coupled between a high voltage rail and a second output node and may be configured to change, based on a first input signal, a voltage level of the second output node. The second input transistor may be coupled between the high voltage rail and a first output node and may be configured to change, based on a second input signal, a voltage level of the first output node. The load circuit may be coupled among the first output node, the second output node, and a low voltage rail and may be configured to increase a total gain of the buffer circuit when a gain adjustment signal is disabled and may be configured to increase an AC gain of the buffer circuit when the gain adjustment signal is enabled.

In an embodiment, a buffer circuit may include a first input transistor, a second input transistor, a first active inductor, a second active inductor, and a switching circuit. The first input transistor may be coupled between a high voltage rail and a second output node and may be configured to receive a first input signal. The second input transistor may be coupled between the high voltage rail and a first output node and may be configured to receive a second input signal. The first active inductor may be coupled between the second output node and a low voltage rail. The second active inductor may be coupled between the first output node and the low voltage rail. The switching circuit may be configured to selectively couple, based on a gain adjustment signal, the first active inductor to the second active inductor.

In an embodiment, a buffer circuit may include a first input transistor, a second input transistor, and a load circuit. The first input transistor may be coupled between a second output node and a low voltage rail and may be configured to change, based on a first input signal, a voltage level of the second output node. The second input transistor may be coupled between a first output node and the low voltage rail and may be configured to change, based on a second input signal, a voltage level of the first output node. The load circuit may be coupled among the first output node, the second output node, and a high voltage rail and may be configured to increase a total gain of the buffer circuit when a gain adjustment signal is disabled and may be configured to increase an AC gain of the buffer circuit when the gain adjustment signal is enabled.

In an embodiment, a buffer circuit may include a first input transistor, a second input transistor, a first active inductor, a second active inductor, and a switching circuit. The first input transistor may be coupled between a second output node and a low voltage rail and may be configured to receive a first input signal. The second input transistor may be coupled between a first output node and the low voltage rail and may be configured to receive a second input signal. The first active inductor may be coupled between a high voltage rail and the second output node. The second active inductor may be coupled between the high voltage rail and the first output node. The switching circuit may be configured to selectively couple, based on a gain adjustment signal, the first active inductor to the second active inductor.

### BRIEF DESCRIPTION OF THE DRAWINGS

FIG. 1 is a diagram illustrating a configuration of a is buffer circuit in accordance with an embodiment.

FIG. 2 is a graph illustrating a gain change of a buffer circuit in accordance with an embodiment.

FIG. 3 is a timing diagram illustrating an operation of a buffer circuit in accordance with an embodiment.

FIG. 4 is a diagram illustrating a configuration of a buffer circuit in accordance with an embodiment.

FIG. 5 is a diagram illustrating a configuration of a semiconductor system in accordance with an embodiment.

FIG. 6 is a diagram illustrating a configuration of a reception circuit in accordance with an embodiment.

### DETAILED DESCRIPTION

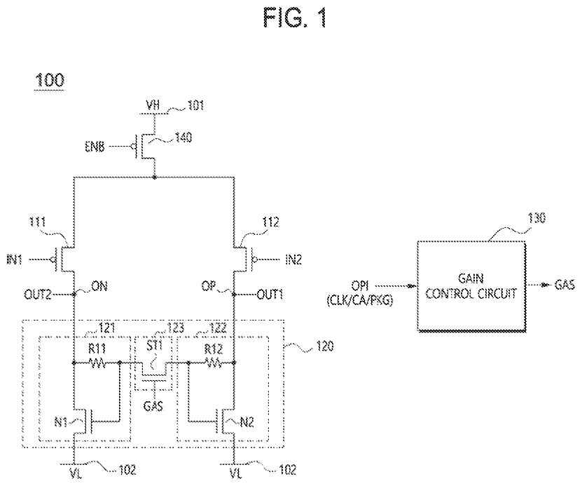

FIG. 1 is a diagram illustrating a configuration of a buffer circuit 100 in accordance with an embodiment. Referring to FIG. 1, the buffer circuit 100 may receive a first input signal IN1 and a second input signal IN2 to generate a first output signal OUT1 and a second output signal OUT2. The second input signal IN2 may be a complementary signal of the first input signal IN1 and may have an opposite logic level to the first input signal IN1. In an embodiment, the second input signal IN2 may be a reference voltage. The reference voltage may have a voltage level that corresponds to the middle of a voltage range, the voltage range being a range within which the first input signal IN1 swings. The second output signal OUT2 may be a complementary signal of the first output signal OUT1 and may have an opposite logic level to the first output signal OUT1. The first output signal OUT1 may be a positive output signal and the second output signal OUT2 may be a negative output signal. The buffer circuit 100 may be coupled to a high voltage rail 101 and a low voltage rail 102 to operate. A first power voltage VH may be applied through the high voltage rail 101 and a second power voltage VL may be applied through the low voltage rail 102. The second power voltage VL may have a voltage level that is lower than the first power voltage VH. For example, the first power voltage VH may be a supply voltage, and the second power voltage VL may be a ground voltage. The buffer circuit 100 may change voltage levels of a first output node OP and a second output node ON based on the first input signal IN1 and the second input signal IN2, thereby generating the first output signal OUT1 and the second output signal OUT2. The first output node OP may be a positive output node, and the second output node ON may be a negative output node. The buffer circuit 100 may be a differential amplifier configured to differentially amplify the first input signal IN1 and the second input signal IN2 to generate the first output signal OUT1 and the second output signal OUT2.

The buffer circuit 100 may further receive a gain adjustment signal GAS. Based on the gain adjustment signal GAS, the buffer circuit 100 may increase the total gain of the buffer circuit 100 or may increase the AC (Alternating Current) gain of the buffer circuit 100. The total gain may be the DC (Direct Current) gain and may be obtained at a relatively lower frequency. The AC gain may be obtained at a relatively higher frequency. Based on the gain adjustment signal GAS, the buffer circuit 100 may increase the total gain of the buffer circuit 100 to increase the effective duration of the first output signal OUT1 and the second output signal OUT2. Based on the gain adjustment signal GAS, the buffer circuit 100 may increase the AC gain of the buffer circuit 100 to adjust the duty ratios of the first output signal OUT1 and the second output signal OUT2. The buffer circuit 100 may increase the total gain or the AC gain according to an operational status of a semiconductor apparatus including the buffer circuit 100.

The buffer circuit 100 may include a first input transistor 111, a second input transistor 112, and a load circuit 120. The first input transistor 111 may be coupled between the high voltage rail 101 and the second output node ON, and the first input transistor 111 may receive the first input signal IN1. Based on the first input signal IN1, the first input transistor 111 may change the voltage level of the second output node ON. The second output signal OUT2 may be output through the second output node ON. The second input transistor 112 may be coupled between the high voltage rail 101 and the first output node OP, and the second input transistor 112 may receive the second input signal IN2. Based on the second input signal IN2, the second input transistor 112 may change the voltage level of the first output node OP. The first output signal OUT1 may be output through the first output node OP.

Each of the first input transistor 111 and the second input transistor 112 may be a P-channel MOS transistor. When the first input signal IN1 has a sufficiently low voltage level that can be determined as a logic low level, the first input transistor 111 may change the voltage level of the second output node ON to the voltage level of the first power voltage VH. When the second input signal IN2 has a sufficiently low voltage level that can be determined as a logic low level, the second input transistor 112 may change the voltage level of the first output node OP to the voltage level of the first power voltage VH. The first input transistor 111 may be coupled to the high voltage rail 101 at its source, may be coupled to the second output node ON at its drain, and may receive the first input signal IN1 at its gate. The second input transistor 112 may be coupled to the high voltage rail 101 at its source, may be coupled to the first output node OP at its drain, and may receive the second input signal IN2 at its gate.

The load circuit 120 may be coupled among the first output node OP, the second output node ON, and the low voltage rail 102. According to the voltage levels of the first output node OP and the second output node ON, the load circuit 120 may couple the first output node OP and the second output node ON to the low voltage rail 102 to lower the voltage levels of the first output node OP and the second output node ON. The load circuit 120 may receive the gain adjustment signal GAS. Based on the gain adjustment signal GAS, the load circuit 120 may increase the total gain of the buffer circuit 100 or the AC gain of the buffer circuit 100. For example, the load circuit 120 may increase the total gain of the buffer circuit 100 when the gain adjustment signal GAS is disabled and may increase the AC gain of the buffer circuit 100 when the gain adjustment signal GAS is enabled. For example, the gain adjustment signal GAS may be enabled to a logic low level.

The load circuit 120 may include a first active inductor 121, a second active inductor 122 and a switching circuit 123. The first active inductor 121 may be coupled between the second output node ON and the low voltage rail 102. The second active inductor 122 may be coupled between the first output node OP and the low voltage rail 102. The switching circuit 123 may receive the gain adjustment signal GAS. Based on the gain adjustment signal GAS, the switching circuit 123 may selectively couple the first active inductor 121 and the second active inductor 122 to each other. When the gain adjustment signal GAS is disabled, the switching circuit 123 may electrically couple the first active inductor 121 and the second active inductor 122 to each other. When the gain adjustment signal GAS is enabled, the switching circuit 123 may electrically isolate the first active inductor 121 and the second active inductor 122 from each other.

The first active inductor 121 may include a first transistor N1 and a first resistive element R11. The first transistor N1 may be coupled between the second output node ON and the low voltage rail 102. The first resistive element R11 may be coupled between the second output node ON and a gate of the first transistor N1. The first transistor N1 may be a N-channel MOS transistor. The first transistor N1 may be coupled to the second output node ON at its drain, may be coupled to the low voltage rail 102 at its source, and may be coupled to the other end of the first resistive element R11 at its gate.

The second active inductor 122 may include a second transistor N2 and a second resistive element R12. The second transistor N2 may be coupled between the first output node OP and the low voltage rail 102. The second resistive element R12 may be coupled to the first output node OP at one end thereof and may be coupled to a gate of the second transistor N2 at the other end thereof.

The second transistor N2 may be a N-channel MOS transistor. The second transistor N2 may be coupled to the first output node OP at its drain, may be coupled to the low voltage rail 102 at its source, and may be coupled to the other end of the second resistive element R12 at its gate.

The switching circuit 123 may include a switch transistor ST1. The switch transistor ST1 may be coupled between the ends of the first resistive element R11 and the second resistive element R12 that are coupled to the gates of the first and second transistors N1 and N2. The switch transistor ST1 may receive the gain adjustment signal GAS at its gate. The switch transistor ST1 may be a N-channel MOS transistor. The switch transistor ST1 may be coupled to the gate of the first transistor N1 and the other end of the first resistive element R11 at one of its drain and source, and the switch transistor ST1 may be coupled to the gate of the second transistor N2 and the other end of the second resistive element R12 at the other one of its drain and source.

The buffer circuit 100 may further include a gain control circuit 130. The gain control circuit 130 may receive operational information OPI to provide the gain adjustment signal GAS. The operational information OPI may be any information representing various operational parameters of a semiconductor apparatus including the buffer circuit 100. For example, the operational information OPI may include at least one of a command address signal CA, package information PKG, and a frequency of a clock signal CLK. The gain control circuit 130 may generate the gain adjustment signal GAS based at least in part on the command address signal CA, the package information PKG, and the frequency of the clock signal CLK. The frequency of the clock signal CLK may be information regarding the operational speed of the semiconductor apparatus. The gain control circuit 130 may generate the gain adjustment signal GAS based on the frequency of the clock signal CLK. The frequency of the clock signal CLK may be related to the operational speed of the semiconductor apparatus. The operational speed of the semiconductor apparatus may become faster as the frequency of the clock signal CLK becomes higher and may become slower as the frequency of the clock signal CLK becomes lower. For example, the gain control circuit 130 may keep the gain adjustment signal GAS disabled when the frequency of the clock signal CLK is relatively low. The gain control circuit 130 may enable the gain adjustment signal

GAS when the frequency of the clock signal CLK is relatively high. The command address signal CA may be a signal for directing the semiconductor apparatus to perform various operations.

The command address signal CA may include information for designating an operational mode of the buffer circuit 100. For example, the gain control circuit 130 may keep the gain adjustment signal GAS disabled when receiving the command address signal CA with information regarding a first operational mode. The gain control circuit 130 may enable the gain adjustment signal GAS when receiving the command address signal CA with information regarding a second operational mode. The first operational mode may be a mode for increasing the total gain of the buffer circuit 100, and the second operational mode may be a mode for increasing the AC gain of the buffer circuit 100. Based on the command address signal CA, the gain control circuit 130 may adjust the timepoint at which the gain adjustment signal GAS is enabled. For example, when the semiconductor apparatus operates at a high speed and the command address signal CA directs the semiconductor apparatus to perform a write operation, the gain control circuit 130 may enable the gain adjustment signal GAS a predetermined amount of time after the timepoint at which the gain control circuit 130 receives the command address signal CA. The buffer circuit 100 may receive the first input signal IN1 and/or the second input signal IN2 during a write operation of the semiconductor apparatus. The predetermined amount of time may be a latency and may represent the delay time from when the command address signal CA is input to the semiconductor apparatus to when the first input signal IN1 and/or the second input signal IN2 are input to the buffer circuit 100.

The package information PKG may include information regarding signal transmission characteristics of the semiconductor apparatus. For example, when the buffer circuit 100 receives the first input signal IN1 and/or the second input signal IN2 within the semiconductor apparatus of a Package on Package (PoP), the package information PKG may have a logic high level. Within the Package on Package, even though a load of a signal path may be small and the swing range of a signal that is transferred through the signal path may be great, a duty adjustment operation may be required because the signal is transferred at a high speed. Therefore, the gain control circuit 130 may enable the gain adjustment signal GAS based on the package information PKG with a logic high level. When the buffer circuit 100 receives the first input signal IN1 and/or the second input signal IN2 within the semiconductor apparatus of a Multi-Chip Package (MCP), the package information PKG may have a logic low level. Within the Multi-Chip Package, even though a load of a signal path may be great and a swing range of a signal that is transferred through the signal path may be small, a high gain may be required rather than a duty adjustment operation because the signal is transferred at a low speed. Therefore, the gain control circuit 130 may disable the gain adjustment signal GAS based on the package information PKG with a logic low level.

The buffer circuit 100 may further include an enable transistor 140. Based on a buffer enable signal ENB, the enable transistor 140 may couple the high voltage rail 101 to each of the first input transistor 111 and the second input transistor 112. When the enable transistor 140 is turned on according to the buffer enable signal ENB, the first power voltage VH may be provided to the first input transistor 111 and the second input transistor 112. The buffer enable signal ENB may be enabled to a logic low level to activate the buffer circuit 100. The buffer enable signal ENB may be provided from a semiconductor apparatus with the buffer circuit 100. The enable transistor 140 may be a P-channel MOS transistor. The enable transistor 140 may be coupled to the high voltage rail 101 at its source, may be in common coupled to the sources of the first input transistor 111 and the second input transistor 112 at its drain, and may receive the buffer enable signal ENB at its gate.

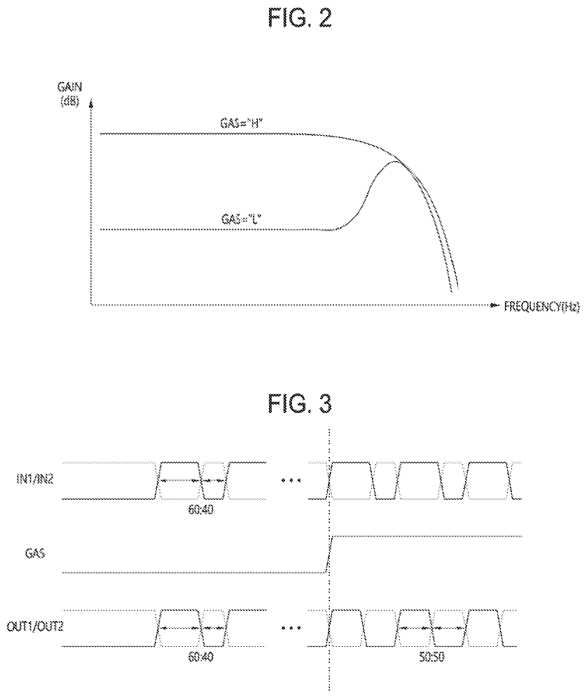

FIG. 2 is a graph illustrating a gain change of a buffer circuit in accordance with an embodiment. Referring to FIGS. 1 and 2, when the gain adjustment signal GAS is disabled to a logic high level (“H”), the switch transistor ST1 may be turned on and the first active inductor 121 and the second active inductor 122 may be coupled to each other. When the first active inductor 121 and the second active inductor 122 are coupled to each other, the buffer circuit 100 may have a structure of a self-biased amplifier, and therefore, the buffer circuit 100 may have a relatively high total gain and/or DC gain. The gain of the buffer circuit 100 may be kept with a relatively high value at a relatively low frequency range and may decrease at a relatively high frequency range. When the gain adjustment signal GAS is enabled to a logic low level (“L”), the switch transistor ST1 may be turned off, and the first active inductor 111 and the second active inductor 112 may be electrically isolated from each other. Therefore, the total gain and/or DC gain of the buffer circuit 100 may decrease. Instead, the AC gain of the buffer circuit 100 may increase. The DC gain of the buffer circuit 100, when the gain adjustment signal GAS is enabled, may be smaller than the DC gain of the buffer circuit 100 when the gain adjustment signal GAS is disabled. However, the buffer circuit 100 may have a relatively high gain at a relatively high frequency range. That is, as the first active inductor 111 and the second active inductor 112 are electrically isolated from each other, inductive peaking may occur in the gain of the buffer circuit 100, and the AC gain of the buffer circuit 100 may have a relatively high value compared to the DC gain of the buffer circuit 100.

FIG. 3 is a timing diagram illustrating an operation of a buffer circuit in accordance with an embodiment. Hereinafter, an operation of the buffer circuit 100, described with reference to FIGS. 1 to 3, will be disclosed. FIG. 3 exemplifies the first input signal IN1 and the second input signal IN2 as differential signals and the second input signal IN2 as a complementary signal of the first input signal IN1. The buffer circuit 100 may differentially amplify the first input signal IN1 and the second input signal IN2 to generate the first output signal OUT1 with a logic level that corresponds to the first input signal IN1 and the second output signal OUT2 with a logic level that corresponds to the second input signal IN2. When the gain adjustment signal GAS is disabled, the switch transistor ST1 may be turned on and the buffer circuit 100 may have a relatively high total gain and/or DC gain. The buffer circuit 100 may differentially amplify the first input signal IN1 and the second input signal IN2 to generate the first output signal OUT1 and the second output signal OUT2 that swing within a greater range than a range within which the first input signal IN1 and the second input signal IN2 swing. However, because the characteristics of the first input signal IN1 and the second input signal IN2 still remain in the first output signal OUT1 and the second output signal OUT2, the duty ratio of the first output signal OUT1 and the second output signal OUT2 may be kept as a ratio of 60:40 when the duty ratio of the first input signal IN1 and the second input signal IN2 is distorted to the ratio of 60:40. The duty ratio may be a ratio between a logic high level pulse section of the first input signal IN1 or the first output signal OUT1 and a logic high level pulse section of the second input signal IN2 or the second output signal OUT2.

When the gain adjustment signal GAS is enabled, the switch transistor ST1 may be turned off and the buffer circuit 100 may have an AC gain that is greater than the DC gain. When the AC gain increases, inductive peaking may occur in the first output signal OUT1 and the second output signal OUT2 as the logic levels of the first output signal OUT1 and the second output signal OUT2 transition. When inductive peaking occurs in the first output signal OUT1 and the second output signal OUT2 at the timepoint of the transition of the logic levels of the first output signal OUT1 and the second output signal OUT2, the duty ratio of the first output signal OUT1 and the second output signal OUT2 may be adjusted. Therefore, the duty ratio of the first output signal OUT1 and the second output signal OUT2 may be adjusted to a ratio of 50:50.

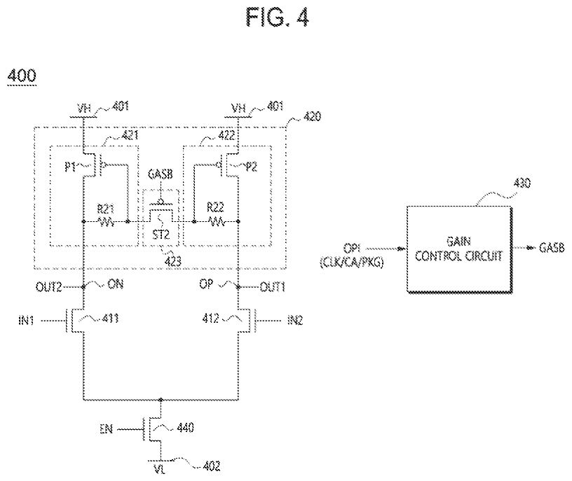

FIG. 4 is a diagram illustrating a configuration of a buffer circuit 400 in accordance with an embodiment. Referring to FIG. 4, the buffer circuit 400 may receive a first input signal IN1 and a second input signal IN2 to generate a first output signal OUT1 and a second output signal OUT2. The second input signal IN2 may be a complementary signal of the first input signal IN1 and may have an opposite logic level to the first input signal IN1. In an embodiment, the second input signal IN2 may be a reference voltage. The reference voltage may have a voltage level that corresponds to the middle of a voltage range, the voltage range being a range within which the first input signal IN1 swings. The second output signal OUT2 may be a complementary signal of the first output signal OUT1 and may have an opposite logic level to the first output signal OUT1. The buffer circuit 400 may be coupled to a high voltage rail 401 and a low voltage rail 402 to operate. A first power voltage VH may be applied through the high voltage rail 401 and a second power voltage VL may be applied through the low voltage rail 402. The second power voltage VL may have a voltage level that is lower than the first power voltage VH. For example, the first power voltage VH may be a supply voltage, and the second power voltage VL may be a ground voltage. The buffer circuit 400 may change the voltage levels of a first output node OP and a second output node ON based on the first input signal IN1 and the second input signal IN2, thereby generating the first output signal OUT1 and the second output signal OUT2. The buffer circuit 400 may be a differential amplifier configured to differentially amplify the first input signal IN1 and the second input signal IN2 to generate the first output signal OUT1 and the second output signal OUT2.

The buffer circuit 400 may further receive a gain adjustment signal GASB. Based on the gain adjustment signal GASB, the buffer circuit 400 may increase the total gain of the buffer circuit 400 or may increase the AC gain of the buffer circuit 400. Based on the gain adjustment signal GASB, the buffer circuit 400 may increase the total gain of the buffer circuit 400 to increase the effective duration of the first output signal OUT1 and the second output signal OUT2. Based on the gain adjustment signal GASB, the buffer circuit 400 may increase the AC gain of the buffer circuit 400 to adjust the duty ratio of the first output signal OUT1 and the second output signal OUT2.

The first input transistor 411 may be coupled between the second output node ON and the low voltage rail 402 and may receive the first input signal IN1. Based on the first input signal IN1, the first input transistor 411 may change the voltage level of the second output node ON. The second output signal OUT2 may be output through the second output node ON. The second input transistor 412 may be coupled between the first output node OP and the low voltage rail 401 and may receive the second input signal IN2. Based on the second input signal IN2, the second input transistor 412 may change the voltage level of the first output node OP. The first output signal OUT1 may be output through the first output node OP.

Each of the first input transistor 411 and the second input transistor 412 may be an N-channel MOS transistor. When the first input signal IN1 has a sufficiently high voltage level that can be determined as a logic high level, the first input transistor 411 may change the voltage level of the second output node ON to the voltage level of the second power voltage VL. When the second input signal IN2 has a sufficiently high voltage level that can be determined as a logic high level, the second input transistor 412 may change the voltage level of the first output node OP to the voltage level of the second power voltage VL. The first input transistor 411 may be coupled to the second output node ON at its drain, may be coupled to the low voltage rail 402 at its source, and may receive the first input signal IN1 at its gate. The second input transistor 412 may be coupled to the first output node OP at its drain, may be coupled to the low voltage rail 402 at its source, and may receive the second input signal IN2 at its gate.

The load circuit 420 may be coupled among the first output node OP, the second output node ON, and the high voltage rail 401. According to the voltage levels of the first output node OP and the second output node ON, the load circuit 420 may couple the first output node OP and the second output node ON to the high voltage rail 401 to raise the voltage levels of the first output node OP and the second output node ON. The load circuit 420 may receive the gain adjustment signal GASB. Based on the gain adjustment signal GASB, the load circuit 420 may increase the total gain of the buffer circuit 400 or the AC gain of the buffer circuit 400. For example, the load circuit 420 may increase the total gain of the buffer circuit 400 when the gain adjustment signal GASB is disabled and may increase the AC gain of the buffer circuit 400 when the gain adjustment signal GASB is enabled. For example, the gain adjustment signal GASB may be enabled to a logic high level.

The load circuit 420 may include a first active inductor 421, a second active inductor 422, and a switching circuit 423. The first active inductor 421 may be coupled between the high voltage rail 401 and the second output node ON. The second active inductor 422 may be coupled between the high voltage rail 401 and the first output node OP. The switching circuit 423 may receive the gain adjustment signal GASB. Based on the gain adjustment signal GASB, the switching circuit 423 may selectively couple the first active inductor 421 and the second active inductor 422 to each other. When the gain adjustment signal GASB is disabled, the switching circuit 423 may electrically couple the first active inductor 421 and the second active inductor 422 to each other. When the gain adjustment signal GASB enabled, the switching circuit 423 may electrically isolate the first active inductor 421 and the second active inductor 422 from each other.

The first active inductor 421 may include a first transistor P1 and a first resistive element R21. The first transistor P1 may be coupled between the high voltage rail 401 and the second output node ON. The first resistive element R21 may be coupled between the second output node ON and a gate of the first transistor P1. The first transistor P1 may be a P-channel MOS transistor. The first transistor P1 may be coupled to the high voltage rail 401 at its source, may be coupled to the second output node ON at its drain, and may be coupled to the other end of the first resistive element R21 at its gate.

The second active inductor 422 may include a second transistor P2 and a second resistive element R22. The second transistor P2 may be coupled between the high voltage rail 401 and the first output node OP. The second resistive element R22 may be coupled to the first output node OP at one end thereof and may be coupled to a gate of the second transistor P2 at the other end thereof. The second transistor P2 may be a P-channel MOS transistor. The second transistor P2 may be coupled to the high voltage rail 401 at its source, may be coupled to the first output node OP at its drain, and may be coupled to the other end of the second resistive element R22 at its gate.

The switching circuit 423 may include a switch transistor ST2. The switch transistor ST2 may be coupled between the ends of the first resistive element R21 and the second resistive element R22 that are coupled to the gates of the first and second transistors P1 and P2. The switch transistor ST2 may receive the gain adjustment signal GASB at its gate. The switch transistor ST2 may be a P-channel MOS transistor. The switch transistor ST2 may be coupled to the gate of the first transistor P1 and the other end of the first resistive element R21 at one of its drain and source, and the switch transistor ST2 may be coupled to the gate of the second transistor P2 and the other end of the second resistive element R22 at the other one of its drain and source.

The buffer circuit 400 may further include a gain control circuit 430. The gain control circuit 430 may receive operational information OPI to provide the gain adjustment signal GASB. The operational information OPI may be any information representing various operational parameters of a semiconductor apparatus including the buffer circuit 400. For example, the operational information OPI may include at least one of a command address signal CA, package information PKG, and a frequency of a clock signal CLK. The gain control circuit 430 may generate the gain adjustment signal GASB based at least in part on the command address signal CA, the package information PKG, and the frequency of the clock signal CLK. The gain control circuit 430 may keep the gain adjustment signal GASB disabled when the frequency of the clock signal CLK is relatively low. The gain control circuit 430 may enable the gain adjustment signal GASB when the frequency of the clock signal CLK is relatively high.

The gain control circuit 430 may keep the gain adjustment signal GASB that is disabled when receiving the command address signal CA with information regarding a first operational mode. The gain control circuit 430 may enable the gain adjustment signal GASB when receiving the command address signal CA with information regarding a second operational mode. Based on the command address signal CA, the gain control circuit 430 may adjust the timepoint at which the gain adjustment signal GASB is enabled. For example, when the semiconductor apparatus operates at a high speed and the command address signal CA directs the semiconductor apparatus to perform a write operation, the gain control circuit 430 may enable the gain adjustment signal GASB a predetermined amount of time after the timepoint at which the gain control circuit 430 receives the command address signal CA.

When the buffer circuit 400 receives the first input signal IN1 and/or the second input signal IN2 within the semiconductor apparatus of a Package on Package (PoP), the package information PKG may have a logic high level. The gain control circuit 430 may enable the gain adjustment signal GASB based on the package information PKG with a logic high level. When the buffer circuit 400 receives the first input signal IN1 and/or the second input signal IN2 within the semiconductor apparatus of a Multi-Chip Package (MCP), the package information PKG may have a logic low level. The gain control circuit 430 may disable the gain adjustment signal GASB based on the package information PKG with a logic low level.

The buffer circuit 400 may further include an enable transistor 440. Based on a buffer enable signal EN, the enable transistor 440 may couple the low voltage rail 402 to each of the first input transistor 411 and the second input transistor 412. When the enable transistor 440 is turned on according to the buffer enable signal EN, the second power voltage VL may be provided to the first input transistor 411 and the second input transistor 412. The buffer enable signal EN may be enabled to a logic high level to activate the buffer circuit 400. The buffer enable signal EN may be provided from a semiconductor apparatus with the buffer circuit 400. The enable transistor 440 may be a N-channel MOS transistor. The enable transistor 440 may be in common coupled to the sources of the first input transistor 411 and the second input transistor 412 at its drain, may be coupled to the low voltage rail 402 at its source, and may receive the buffer enable signal EN at its gate.

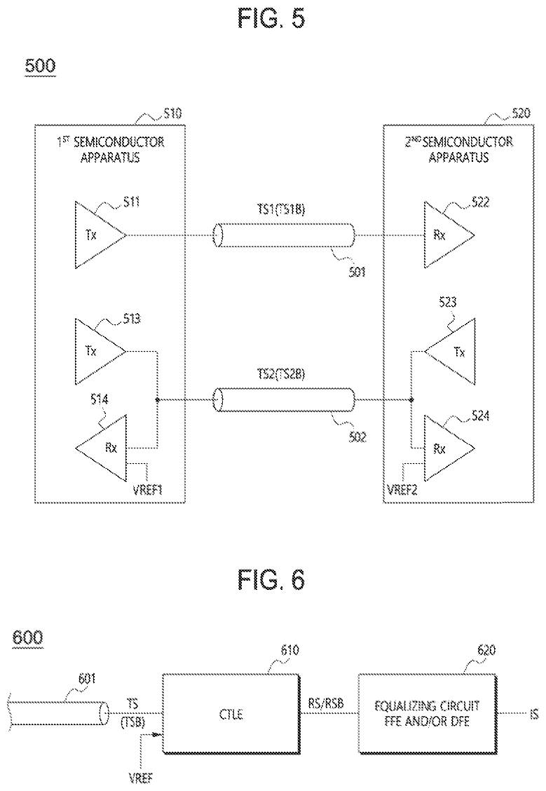

FIG. 5 is a diagram illustrating a configuration of a semiconductor system 5 in accordance with an embodiment. Referring to FIG. 5, the semiconductor system 5 may include a first semiconductor apparatus 510 and a second semiconductor apparatus 520. The first semiconductor apparatus 510 may provide various control signals that are required for the second semiconductor apparatus 520 to operate. The first semiconductor apparatus 510 may include various types of host devices. For example, the first semiconductor apparatus 510 may be a host device such as a central processing unit (CPU), a graphic processing unit (GPU), a multi-media processor (MMP), a digital signal processor, an application processor (AP) and a memory controller. For example, the second semiconductor apparatus 520 may be a memory device and the memory device may include a volatile memory and a nonvolatile memory. The volatile memory may include a static random access memory (static RAM: SRAM), a dynamic RAM (DRAM) and a synchronous DRAM (SDRAM). The nonvolatile memory may include a read only memory (ROM), a programmable ROM (PROM), an electrically erasable and programmable ROM (EEPROM), an electrically programmable ROM (EPROM), a flash memory, a phase change RAM (PRAM), a magnetic RAM (MRAM), a resistive RAM (RRAM), a ferroelectric RAM (FRAM) and so forth.

The second semiconductor apparatus 520 may be coupled to the first semiconductor apparatus 510 through a first bus 501 and a second bus 502. Each of the first bus 501 and the second bus 502 may be a signal transmission path, a link, or a channel for transferring a signal. The first bus 501 may be a unidirectional bus. The first semiconductor apparatus 510 may transmit a first signal TS1 to the second semiconductor apparatus 520 through the first bus 501, and the second semiconductor apparatus 520 that is coupled to the first bus 501 may receive the first signal TS1 that is transferred from the first bus 501. For example, the first signal TS1 may include control signals, such as a command signal, a clock signal, an address signal, and so forth. The second bus 502 may be a bidirectional bus. Through the second bus 502, the first semiconductor apparatus 510 may provide the second signal TS2 to the second semiconductor apparatus 520 or may receive the second signal TS2 from the second semiconductor apparatus 520. Through the second bus 502, the second semiconductor apparatus 520 may provide the second signal TS2 to the first semiconductor apparatus 510 or may receive the second signal TS2 from the first semiconductor apparatus 510. For example, the second signal TS2 may be data. In an embodiment, the first signal TS1 and the second signal TS2 may be transferred as differential signals, together with complementary signals TS1B and TS2B, through the first bus 501, and the second bus 502, respectively. In an embodiment, the first signal TS1 and the second signal TS2 may be transferred, as single-ended signals, through the first bus 501 and the second bus 502, respectively.

The first semiconductor apparatus 510 may include a first transmission circuit (TX) 511, a second transmission circuit (TX) 513, and a reception circuit (RX) 514. The first transmission circuit 511 may be coupled to the first bus 501. Based on an internal signal of the first semiconductor apparatus 510, the first transmission circuit 511 may drive the first bus 501 to provide the first signal TS1 to the second semiconductor apparatus 520. The second transmission circuit 513 may be coupled to the second bus 502. Based on an internal signal of the first semiconductor apparatus 510, the second transmission circuit 513 may drive the second bus 502 to provide the second signal TS2 to the second semiconductor apparatus 520. The reception circuit 514 may be coupled to the second bus 502. The reception circuit 514 may receive the second signal TS2 that is transferred from the second semiconductor apparatus 520 through the second bus 502. The reception circuit 514 may differentially amplify the second signal TS2 that is transferred through the second bus 502 to generate an internal signal that is to be utilized within the first semiconductor apparatus 510. When a pair of differential signals is transferred through the second bus 502, the reception circuit 514 may differentially amplify the second signal TS2 and the complementary signal TS2B of the second signal TS2 to generate the internal signal. When a single-ended signal is transferred through the second bus 502, the reception circuit 514 may differentially amplify the second signal TS2 and a first reference voltage VREF1 to generate the internal signal. The first reference voltage VREF1 may have a voltage level that corresponds to the middle of a voltage range, the voltage range being a range within which the second signal TS2 swings. The reception circuit 514 may include the buffer circuits 100 and 400, illustrated in FIGS. 1 and 4.

The second semiconductor apparatus 520 may include a first reception circuit (RX) 522, a transmission circuit (TX) 523 and a second reception circuit (RX) 524. The first reception circuit 522 may be coupled to the first bus 501. The first reception circuit 522 may receive the first signal TS1 that is transferred from the first semiconductor apparatus 510 through the first bus 501. The first reception circuit 522 may differentially amplify the first signal TS1 that is transferred through the first bus 501 to generate an internal signal that is to be utilized within the second semiconductor apparatus 520. When a pair of differential signals is transferred through the first bus 501, the first reception circuit 522 may differentially amplify the first signal TS1 and the complementary signal TS1B of the first signal TS1 to generate the internal signal. When a single-ended signal is transferred through the first bus 501, the first reception circuit 522 may differentially amplify the first signal TS1 and a second reference voltage VREF2 to generate the internal signal. The second reference voltage VREF2 may have a voltage level that corresponds to the middle of a voltage range, the voltage range being a range within which the first signal TS1 swings. The transmission circuit 523 may be coupled to the second bus 502. Based on an internal signal of the second semiconductor apparatus 520, the transmission circuit 523 may drive the second bus 502 to provide the second signal TS2 to the first semiconductor apparatus 510. The second reception circuit 524 may be coupled to the second bus 502. The second reception circuit 524 may receive the second signal TS2 that is transferred from the first semiconductor apparatus 510 through the second bus 502. The second reception circuit 524 may differentially amplify the second signal TS2 transferred through the second bus 502 to generate an internal signal that is to be utilized within the second semiconductor apparatus 520. When a pair of differential signals is transferred through the second bus 502, the second reception circuit 524 may differentially amplify the second signal TS2 and the complementary signal TS2B of the second signal TS2 to generate the internal signal. When a single-ended signal is transferred through the second bus 502, the second reception circuit 524 may differentially amplify the second signal TS2 and the first reference voltage VREF1 to generate the internal signal. The first reception circuit 522 and the second reception circuit 524 may include the buffer circuits 100 and 400, illustrated in FIGS. 1 and 4.

FIG. 6 is a diagram illustrating a configuration of a reception circuit 600 in accordance with an embodiment. The reception circuit 600 may be applied as each of the reception circuit 514, the first reception circuit 522, and the second reception circuit 524, illustrated in FIG. 5. The reception circuit 600 may include a continuous time linear equalizer (CTLE) 610 and an equalizing circuit 620. The reception circuit 600 may be coupled to an external bus 601 or a channel and may receive a transmitted signal TS that is transferred through the external bus 601. The reception circuit 600 may generate an internal signal IS from the transmitted signal TS. The transmitted signal TS may experience Inter Symbol Interference (ISI) due to high frequency loss, reflection, or crosstalk of the external bus 601 or the channel. Therefore, due to a previously transmitted signal, a signal that is to be subsequently transmitted may experience precursor interference. The continuous time linear equalizer 610 and the equalizing circuit 620 may be provided in order to minimize the precursor interference.

The continuous time linear equalizer 610 may be coupled to the external bus 601 and may receive the transmitted signal TS that is transferred through the external bus 601. The continuous time linear equalizer 610 may differentially amplify the transmitted signal TS to generate a pair of received signals RS and RSB. The pair of received signals may include a received signal RS and a complementary signal RSB. The continuous time linear equalizer 610 may decrease the DC gain and increase the AC gain to precisely amplify the level transition of the transmitted signal TS and generate the received signal RS. The transmitted signal TS may be transmitted as a pair of differential signals, together with a complementary signal TSB, or may be transmitted as a single-ended signal. In order to generate the received signal RS, the continuous time linear equalizer 610 may differentially amplify the transmitted signal TS and complementary signal TSB or may differentially amplify the transmitted signal TS, which is transferred as a single-ended signal, and a reference voltage VREF. The buffer circuits 100 and 400 illustrated in FIGS. 1 and 4 may be applied as the continuous time linear equalizer 610.

The equalizing circuit 620 may receive the pair of received signals RS and RSB and generate the internal signal IS. The equalizing circuit 620 may remove the precursor interference, experienced in the pair of received signals RS and RSB, and may generate the internal signal IS. The equalizing circuit 620 may be implemented in various forms according to a characteristic of a semiconductor apparatus to which the reception circuit 600 is applied. The equalizing circuit 620 may include at least one of a decision feedback equalization circuit and a feed forward equalization circuit.

While certain embodiments have been described above, it will be understood to those skilled in the art that the embodiments described are by way of example only. Accordingly, the buffer circuit capable of adjusting a gain, receiving circuit and semiconductor apparatus including the same should not be limited based on the described embodiments. Rather, the buffer circuit capable of adjusting a gain, receiving circuit and semiconductor apparatus including the same described herein should only be limited in light of the claims that follow when taken in conjunction with the above description and accompanying drawings.

1. A buffer circuit comprising:
a first input transistor coupled between a high voltage rail and a second output node and configured to change, based on a first input signal, a voltage level of the second output node;
a second input transistor coupled between the high voltage rail and a first output node and configured to change, based on a second input signal, a voltage level of the first output node;
a first active inductor coupled between the second output node and a low voltage rail;
a second active inductor coupled between the first output node and the low voltage rail; and
a switching circuit configured to selectively couple, based on a gain adjustment signal, the first active inductor to the second active inductor,
wherein a total gain of the buffer circuit is increased when the switching circuit couples the first and second active inductors, and an AC gain of the buffer circuit is increased when the switching circuit electrically isolates the first and second active inductors.

2. (canceled)

3. The buffer circuit of claim 1, wherein the first active inductor includes:
a first transistor coupled between the second output node and the low voltage rail; and
a first resistive element coupled between the second output node and a gate of the first transistor.

4. The buffer circuit of claim 3,
wherein the second active inductor includes:
a second transistor coupled between the first output node and the low voltage rail; and
a second resistive element coupled between the first output node and a gate of the second transistor, and
wherein the switching circuit is coupled between ends of the first resistive element and the second resistive element that are coupled to the gates of the first and second transistors.

5. The buffer circuit of claim 1, further comprising a gain control circuit configured to generate the gain adjustment signal based on operational information.

6. The buffer circuit of claim 5, wherein the operational information includes at least one of a command address signal, package information, and a frequency of a clock signal.

7. A buffer circuit comprising:
a first input transistor coupled between a high voltage rail and a second output node and configured to receive a first input signal;
a second input transistor coupled between the high voltage rail and a first output node and configured to receive a second input signal;
a first transistor coupled between the second output node and a low voltage rail;
a first resistive element coupled between the second output node and a gate of the first transistor;
a second transistor coupled between the first output node and the low voltage rail;
a second resistive element coupled between the first output node and a gate of the second transistor; and
a switching circuit configured to couple, based on a gain adjustment signal, ends of the first and second resistive elements to the gates of the first and second transistors.

8-9. (canceled)

10. The buffer circuit of claim 7, further comprising a gain control circuit configured to generate the gain adjustment signal based at least in part on a command address signal, package information, and a frequency of a clock signal.

11. A buffer circuit comprising:
a first input transistor coupled between a second output node and a low voltage rail and configured to change, based on a first input signal, a voltage level of the second output node;
a second input transistor coupled between a first output node and the low voltage rail and configured to change, based on a second input signal, a voltage level of the first output node;
a first active inductor coupled between a high voltage rail and the second output node;
a second active inductor coupled between the high voltage rail and the first output node; and
a switching circuit configured to selectively couple, based on a gain adjustment signal, the first active inductor to the second active inductor,
wherein a total gain of the buffer circuit is increased when the switching circuit couples the first and second active inductors, and an AC gain of the buffer circuit is increased when the switching circuit electrically isolates the first and second active inductors.

12. (canceled)

13. The buffer circuit of claim 11, wherein the first active inductor includes:
a first transistor coupled between the high voltage rail and the second output node; and
a first resistive element coupled between the second output node and a gate of the first transistor.

14. The buffer circuit of claim 13,
wherein the second active inductor includes:
a second transistor coupled between the high voltage rail and the first output node; and
a second resistive element coupled between the first output node and a gate of the second transistor, and
wherein the switching circuit is coupled between ends of the first resistive element and the second resistive element that are coupled to the gates of the first and second transistors.

15. The buffer circuit of claim 11, further comprising a gain control circuit configured to generate the gain adjustment signal based at least in part on a command address signal, package information, and a frequency of a clock signal.

16. A buffer circuit comprising:
a first input transistor coupled between a second output node and a low voltage rail and configured to receive a first input signal;
a second input transistor coupled between a first output node and the low voltage rail and configured to receive a second input signal;
a first transistor coupled between a high voltage rail and the second output node;
a first resistive element coupled between the second output node and a gate of the first transistor;
a second transistor coupled between the high voltage rail and the first output node;
a second resistive element coupled between the first output node and a gate of the second transistor; and
a switching circuit configured to couple, based on a gain adjustment signal, ends of the first and second resistive elements to the gates of the first and second transistors.

17-18. (canceled)

19. The buffer circuit of claim 16, further comprising a gain control circuit configured to generate the gain adjustment signal based at least in part on a command address signal, package information, and a frequency of a clock signal.
